(19) United States
(12) Patent Application Publication
(10) Pub. No.: US 2022/0085791 A1
(43) Pub. Date: Mar. 17, 2022

(54) BULK-ACOUSTIC WAVE RESONATOR

(71) Applicant: SAMSUNG ELECTRO-MECHANICS CO., LTD., Suwon-si (KR)

(72) Inventors: Tae Yoon KIM, Suwon-si (KR); Won HAN, Suwon-si (KR); Sang Hyun YI, Suwon-si (KR); Jae Hyoung GIL, Suwon-si (KR); Sang Kee YOON, Suwon-si (KR); Moon Chul LEE, Suwon-si (KR)

(73) Assignee: SAMSUNG ELECTRO-MECHANICS CO., LTD., Suwon-si (KR)

(21) Appl. No.: 17/231,330

(22) Filed: Apr. 15, 2021

(30) Foreign Application Priority Data
Sep. 16, 2020 (KR) 10-2020-0118804

(51) Int. Cl. H03H 9/17; H03H 9/02

(52) U.S. Cl. CPC H03H 9/173; H03H 9/02118

(57) ABSTRACT

A bulk-acoustic wave resonator includes: a substrate; a first electrode disposed on the substrate; a cavity disposed between the substrate and the first electrode; a piezoelectric layer covering at least a portion of the first electrode; a second electrode covering at least a portion of the piezoelectric layer; an insertion layer disposed between the first electrode and the piezoelectric layer; and a lower frame disposed in the cavity. At least a portion of the lower frame overlaps the insertion layer.

### CROSS-REFERENCE TO RELATED APPLICATIONS

This application claims the benefit under 35 U.S.C. § 119(a) of Korean Patent Application No. 10-2020-0118804 filed on Sep. 16, 2020 in the Korean Intellectual Property Office, the entire disclosure of which is incorporated herein by reference for all purposes.

### BACKGROUND

### 1. Field

The following description relates to a bulk-acoustic wave resonator.

### 2. Description of Related Art

In general, a bulk-acoustic wave resonator (BAW) may operate using vibrations in a thickness mode, propagating from electrodes in a vertical direction by stacking a lower electrode, a piezoelectric layer, and an upper electrode, as an ideal fundamental mode.

However, in practice, a transverse mode in which vibrations propagate from electrodes in a horizontal direction, may occur. As a result, a lateral/horizontal wave may leak from an end of the resonator toward an outside of the resonator, to deteriorate quality factor (Q) performance and attenuation performance.

Accordingly, it is desirable to develop a structure in which the leakage of lateral waves is reduced to improve quality factor (Q) and attenuation performance.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a bulk-acoustic wave resonator includes: a substrate; a first electrode disposed on the substrate; a cavity disposed between the substrate and the first electrode; a piezoelectric layer covering at least a portion of the first electrode; a second electrode covering at least a portion of the piezoelectric layer; an insertion layer disposed between the first electrode and the piezoelectric layer; and a lower frame disposed in the cavity. At least a portion of the lower frame overlaps the insertion layer.

A medial side surface of the lower frame may protrude from a medial end of the insertion layer toward an active area in which the first electrode, the piezoelectric layer, and the second electrode overlap.

A width of a region in which a medial end portion of the insertion layer and an end portion of the second electrode overlap may be 0.2 μm to 0.8 μm.

A distance between a medial end of the insertion layer and a medial end of the lower frame, in a medial direction of the bulk-acoustic wave resonator, may be 0.4 μm to 1.2 μm.

A thickness of the lower frame may be 0.08 μm to 0.15 μm.

A medial side surface of the lower frame may be spaced apart from a medial end of the insertion layer toward an outside of an active area in which the first electrode, the piezoelectric layer, and the second electrode overlap.

The bulk-acoustic wave resonator may further include a membrane layer forming the cavity together with the substrate.

The bulk-acoustic wave resonator may further include: an etch-preventing portion disposed to surround the cavity; a sacrificial layer disposed to surround the etch-preventing portion; and a metal pad connected to the first electrode and the second electrode.

A lateral side surface of the lower frame may be spaced apart from a medial side surface of the metal pad toward an active area in which the first electrode, the piezoelectric layer, and the second electrode overlap.

A width of a region in which a medial end portion of the insertion layer and an end portion of the second electrode overlap may be 0.2 μm to 0.8 μm.

A thickness of the lower frame may be 0.08 μm to 0.15 μm.

A lateral side surface of the lower frame may be spaced apart from a medial side surface of the metal pad toward an outside of an active area in which the first electrode, the piezoelectric layer, and the second electrode overlap.

The lower frame may be connected to the etch-preventing portion.

The lower frame may be a portion of the etch-preventing portion.

The lower frame may extend from a remaining portion of the etch-preventing portion toward a center of an active area in which the first electrode, the piezoelectric layer, and the second electrode overlap. A thickness of the lower frame may be less than a thickness of the remaining portion of the etch-preventing portion.

In another general aspect, a bulk-acoustic wave resonator includes: a substrate; a cavity disposed on the substrate; a lower electrode disposed on an upper portion of the cavity; a piezoelectric layer disposed on the lower electrode; an upper electrode disposed on the piezoelectric layer such that the piezoelectric layer is disposed between the first electrode and the second electrode; an insertion layer disposed between portions of the lower electrode and the piezoelectric layer; and a lower frame disposed in the cavity, on a lower surface of lower electrode, such that the lower frame at least partially overlaps the insertion layer.

The lower frame may extend farther than the insertion layer in a horizontal direction toward a center of the bulk-acoustic wave resonator.

The insertion layer may extend farther than the lower frame in a horizontal direction away from the center of the bulk-acoustic wave resonator.

The lower frame may extend farther than the insertion layer in a horizontal direction away from a center of the bulk-acoustic wave resonator.

Other features and aspects will be apparent from the following detailed description, the drawings, and the claims.

### BRIEF DESCRIPTION OF DRAWINGS

FIG. 1 is a schematic cross-sectional view illustrating a bulk-acoustic wave resonator according, to an embodiment.

FIG. 2 is an enlarged view illustrating portion A of FIG. 1.

FIG. 3 is an illustrative diagram illustrating a conventional bulk-acoustic wave resonator.

FIG. 4 is a graph illustrating attenuation performance according to a BR width in a conventional bulk-acoustic wave resonator.

FIG. 5 is a graph illustrating attenuation performance according to a distance between a medial end of an insertion layer and a medial end of a lower frame, when a BR width is 0.4 μm and 0.6 μm, in the bulk-acoustic wave resonator of FIGS. 1 and 2.

FIG. 6 is a graph illustrating attenuation performance according to a thickness of the lower frame, when a distance between a medial end of an insertion layer and a medial end of the lower frame is 0.8 μm and 1.2 μm, in the bulk-acoustic wave resonator of FIGS. 1 and 2.

FIG. 7 is a schematic cross-sectional view illustrating a bulk-acoustic wave resonator, according to another embodiment.

FIG. 8 is a schematic cross-sectional view illustrating a bulk-acoustic wave resonator, according to another embodiment.

FIG. 9 is a schematic cross-sectional view illustrating a bulk-acoustic wave resonator, according to another embodiment.

FIG. 10 is a schematic cross-sectional view illustrating a bulk-acoustic wave resonator, according to another embodiment.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure. Hereinafter, while embodiments of the present disclosure will be described in detail with reference to the accompanying drawings, it is noted that examples are not limited to the same.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween. As used herein “portion” of an element may include the whole element or less than the whole element.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may be also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

The features of the examples described herein may be combined in various ways as will be apparent after an understanding of this disclosure. Further, although the examples described herein have a variety of configurations, other configurations are possible as will be apparent after an understanding of this disclosure.

Herein, it is noted that use of the term “may” with respect to an example, for example, as to what an example may include or implement, means that at least one example exists in which such a feature is included or implemented while all examples are not limited thereto.

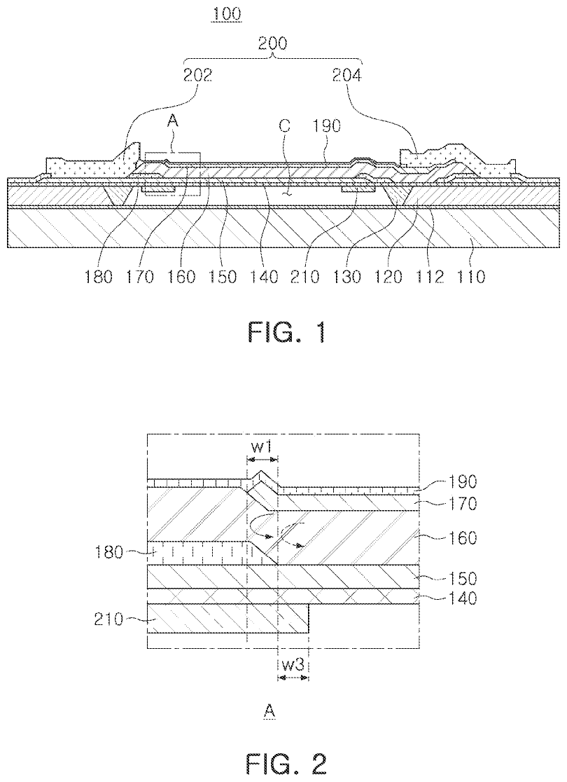

FIG. 1 is a schematic cross-sectional view illustrating a bulk-acoustic wave resonator 100, according to an embodiment. FIG. 2 is an enlarged view illustrating portion A of FIG. 1.

Referring to FIGS. 1 and 2, the bulk-acoustic wave resonator 100 may include, for example, a substrate 110, a sacrificial layer 120, an etch-preventing portion 130, a membrane layer 140, a first electrode 150, a piezoelectric layer 160, a second electrode 170, an insertion layer 180, a passivation layer 190, a metal pad 200, and a lower frame 210.

The substrate 110 may be a silicon substrate. For example, a silicon wafer or a silicon-on-insulator (SOI) type substrate may be used as the substrate 110.

An insulating layer 112 may be formed on an upper surface of the substrate 110, and may electrically isolate the substrate 110 from a structure disposed thereon. In addition, the insulating layer 112 may serve to prevent the substrate 110 from being etched by an etching gas, when a cavity C is formed in a manufacturing process.

The insulating layer 112 may be formed of any one or any combination of any two or more of silicon dioxide (SiO₂), silicon nitride (Si₃N₄), aluminum oxide (Al₂O₂), and aluminum nitride (AlN), and may be formed on the substrate 110 by any one of a chemical vapor deposition process, an RF magnetron sputtering process, and an evaporation process.

The sacrificial layer 120 may be formed on the insulating layer 112, and the cavity C and the etch-preventing portion 130 may be disposed in the sacrificial layer 120. The cavity C may be formed by removing a portion of the sacrificial layer 120 in the manufacturing process. Since the cavity C is formed in the sacrificial layer 120, the first electrode 150 and the like arranged on the sacrificial layer 120 may be formed to be planar.

The etch-prevention portion 130 may be disposed along a boundary of the cavity C. The etch-prevention portion 130 may prevent etching from proceeding beyond an area of the cavity C in an operation of forming the cavity C.

The membrane layer 140 may form the cavity C together with the substrate 110. In addition, the membrane layer 140 may be formed of a material having low reactivity with the etching gas used to remove the sacrificial layer 120. A dielectric layer containing any one material of silicon nitride (Si₃N₄), silicon oxide (SiO₂), manganese oxide (MgO), zirconium oxide (ZrO₂), aluminum nitride (AlN), lead zirconate titanate (PZT), gallium arsenic (GaAs), hafnium oxide (HfO₂), aluminum oxide (Al₂O₃), titanium oxide (TiO₂), and zinc oxide (ZnO) may be used as the membrane layer 140.

A seed layer formed of aluminum nitride (AlN) may be formed on the membrane layer 140. For example, the seed layer may be disposed between the membrane layer 140 and the first electrode 150. The seed layer may be formed using a dielectric material or a metal having an HCP crystal structure, in addition to aluminum nitride (AlN). As an example, in an example in which the seed layer is a metal, the seed layer may be formed of titanium (Ti). The disclosure is not, however, limited to the foregoing example, and the membrane layer 140 may not be provided, and only the seed layer may be formed.

The first electrode 150 may be formed on the membrane layer 140, and a portion of the first electrode 150 may be disposed on an upper portion of the cavity C. In addition, the first electrode 150 may be used as either one of an input electrode and an output electrode for inputting and outputting, respectively, an electrical signal such as a radio frequency (RF) signal or the like.

As an example, the first electrode 150 may be formed of an aluminum alloy material containing scandium (Sc). For example, the first electrode 150 may be formed of an aluminum alloy material containing scandium (Sc) to increase mechanical strength, and allow high power reactive sputtering. Under such deposition conditions, an increase in surface roughness of the first electrode 150 may be prevented, and high orientation growth of the piezoelectric layer 160 may be induced.

In addition, in an example in which the first electrode 150 contains scandium (Sc), chemical resistance of the first electrode 150 may increase, to compensate for a disadvantage that occurs when the first electrode is formed of pure aluminum. Furthermore, stability of a process such as dry etching or wet processing during manufacturing may be secured. Further, when a first electrode is formed of pure aluminum, oxidation may easily occur. Since the first electrode 150 may be formed of an aluminum alloy material containing scandium, chemical resistance against oxidation may be improved.

The first electrode 150 is not limited to being formed of an aluminum alloy material containing scandium (Sc). For example, the first electrode 150 may be formed of a conductive material such as molybdenum (Mo), or an alloy of Mo. However, the first electrode 150 may alternatively be formed of a conductive material such as ruthenium (Ru), tungsten (W), iridium (Ir), platinum (Pt), copper (Cu), titanium (Ti), tantalum (Ta), nickel (Ni), chromium (Cr), or the like, or an alloy of ruthenium (Ru), tungsten (W), iridium (Ir), platinum (Pt), copper (Cu), titanium (Ti), tantalum (Ta), nickel (Ni), or chromium (Cr).

The piezoelectric layer 160 may be formed to cover at least a portion of the first electrode 150 disposed on the upper portion of the cavity C. The piezoelectric layer 160 may be a layer that generates a piezoelectric effect that converts electrical energy into mechanical energy in the form of elastic waves, and may include aluminum nitride (AlN), for example.

In addition, the piezoelectric layer 160 may be doped with a dopant such as a rare earth metal or a transition metal. For example, the rare earth metal used as the dopant may include any one of scandium (Sc), erbium (Er), yttrium (Y), and lanthanum (La). In addition, as an example, the transition metal used as the dopant may include any one of titanium (Ti), zirconium (Zr), hafnium (Hf), tantalum (Ta), and niobium (Nb). In addition, magnesium (Mg), which is a divalent metal, may also be included in the piezoelectric layer 160.

The second electrode 170 may be formed to cover at least a portion of the piezoelectric layer 160 disposed on the upper portion of the cavity C. The second electrode 170 may be configured as either the input electrode or the output electrode for inputting or outputting, respectively, an electrical signal such as a radio frequency (RF) signal or the like. For example, when the first electrode 150 is configured as the input electrode, the second electrode 170 may be configured as the output electrode, and when the first electrode 150 is configured as the output electrode, the second electrode 170 may be configured as the input electrode.

The second electrode 170 is not limited to the foregoing examples. For example, the second electrode 170 may be formed of a conductive material such as molybdenum (Mo) or an alloy of Mo. However, the second electrode 170 is not limited to being formed of Mo, and may be formed of a conductive material such as ruthenium (Ru), tungsten (W), iridium (Ir), platinum (Pt), copper (Cu), titanium (Ti), tantalum (Ta), nickel (Ni), chromium (Cr), or the like, or an alloy of ruthenium (Ru), tungsten (W), iridium (Ir), platinum (Pt), copper (Cu), titanium (Ti), tantalum (Ta), nickel (Ni), or chromium (Cr).

As an example, the second electrode 170 may be formed of an aluminum alloy material containing scandium (Sc). For example, the second electrode 170 may be formed of an aluminum alloy material containing scandium (Sc) to increase mechanical strength, and allow high power reactive sputtering. Under such deposition conditions, an increase in surface roughness of the second electrode 170 may be prevented.

In addition, in an example in which the second electrode 170 contains scandium (Sc), chemical resistance of the second electrode 170 may increase, to compensate for a disadvantage that occurs when the second electrode is formed of pure aluminum. Furthermore, stability of a process such as dry etching or wet processing during manufacturing may be secured. Further, when a second electrode is formed of pure aluminum, oxidation may easily occur. Since the second electrode 170 may be formed of an aluminum alloy material containing scandium (Sc), chemical resistance against oxidation may be improved.

The insertion layer 180 may be disposed between the first electrode 150 and the piezoelectric layer 160. The insertion layer 180 may be formed of a dielectric material such as silicon oxide (SiO₂), aluminum nitride (AlN), aluminum oxide (Al₂O₃), silicon nitride (Si₃N₄), manganese oxide (MgO), zirconium oxide (ZrO₂), lead zirconate titanate (PZT), gallium arsenic (GaAs), hafnium oxide (HfO₂), aluminum oxide (Al₂O₃), titanium oxide (TiO₂), zinc oxide (ZnO), or the like, but may be formed of a material different from the material of the piezoelectric layer 160. In addition, a region in which the insertion layer 180 is provided, as necessary, may be formed as an empty space (air). This may be implemented by removing the insertion layer 180 during the manufacturing process.

As an example, the insertion layer 180 may be disposed along surfaces of the membrane layer 140, the first electrode 150, and the etch-preventing portion 130. In addition, at least a portion of the insertion layer 180 may be disposed between the piezoelectric layer 160 and the first electrode 150.

Referring to FIG. 2, a width of a region in which a medial end portion of the insertion layer 180 and an end portion of the second electrode 170 overlap may be referred to as a BR width w1. The BR width w1 may be 0.2 μm to 0.8 μm, for example.

The passivation layer 190 may be formed in areas excluding portions of the first electrode 150 and the second electrode 170. The passivation layer 190 may prevent damage to the second electrode 170 and the first electrode 150 during an operation of the bulk-acoustic wave resonator 100.

Furthermore, a portion of the passivation layer 190 may be removed by etching for frequency control in a final process. For example, a thickness of the passivation layer 190 may be adjusted. A dielectric layer containing any one material of silicon nitride (Si₃N₄), silicon oxide (SiO₂), manganese oxide (MgO), zirconium oxide (ZrO₂), aluminum nitride (AlN), lead zirconate titanate (PZT), gallium arsenic (GaAs), hafnium oxide (HfO₂), aluminum oxide (Al₂O₃), titanium oxide (TiO₂), and zinc oxide (ZnO) may be used as the passivation layer 190.

The metal pad 200 may be formed on the first electrode 150 and a portion of the second electrode 170 on which the passivation layer 190 is not formed. As an example, the metal pad 200 may be made of a material such as gold (Au), gold-tin (Au—Sn) alloy, copper (Cu), copper-tin (Cu—Sn) alloy, aluminum (Al), aluminum alloy, or the like. For example, the aluminum alloy may be an aluminum-germanium (Al—Ge) alloy.

The metal pad 200 may include a first metal pad 202 connected to the first electrode 150, and a second metal pad 204 connected to the second electrode 170.

The lower frame 210 may be disposed below the membrane layer 140, and may be disposed next to the etch-preventing portion 130 in a medial direction. In addition, the lower frame 210 may have a ring shape, when viewed from above the bulk-acoustic wave resonator 100. That is, the lower frame 210 may have a ring shape in a horizontal plane parallel to the upper surface of the substrate 110. As illustrated in FIG. 2, a medial side surface of the lower frame 210 may be disposed to protrude from a medial end of the insertion layer 180 toward an active area (e.g., toward a central portion of the bulk-acoustic wave resonator 100). In this case, the active area is a region in which the first electrode 150, the piezoelectric layer 160, and the second electrode 170 overlap one another.

In addition, the lower frame 210 may be formed of an insulating material such as silicon oxide (SiO₂) or silicon nitride (SiN), a piezoelectric material such as pure or rare earth-doped aluminum nitride (AlN) or the like, or a material such as molybdenum (Mo), ruthenium (Ru), tungsten (W), iridium (Ir), platinum (Pt), copper (Cu), titanium (Ti), tantalum (Ta), nickel (Ni), chromium (Cr), and the like, or an alloy of molybdenum (Mo), ruthenium (Ru), tungsten (W), iridium (Ir), platinum (Pt), copper (Cu), titanium (Ti), tantalum (Ta), nickel (Ni), or chromium (Cr).

In addition, a distance w3 between a medial end of the insertion layer 180 and a medial end of the lower frame 210 may be 0.4 μm to 1.2 μm. A thickness of the lower frame may be 0.08 μm to 0.15 μm, for example.

As illustrated in FIG. 2, a lateral wave may be first reflected from the lower frame 210, and a transmitted lateral wave may be additionally reflected from the medial end of the insertion layer 180. In this manner, reflection characteristics and Q performance may be improved by the lower frame 210 being disposed in the cavity C so as to be disposed in an edge portion of the active area. This may be because a long wave among the lateral waves first meets and is reflected from the lower frame 210 and, and a short wave having good penetration power among the lateral waves meets and is additionally reflected the insertion layer.

Effects due to the lower frame 210 will be described in more detail below.

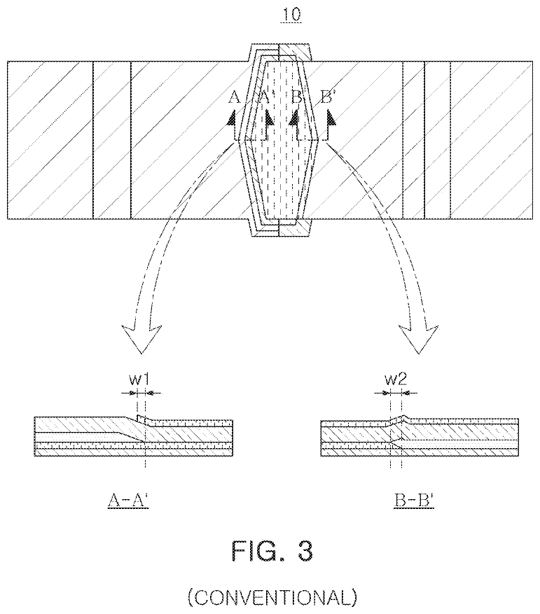

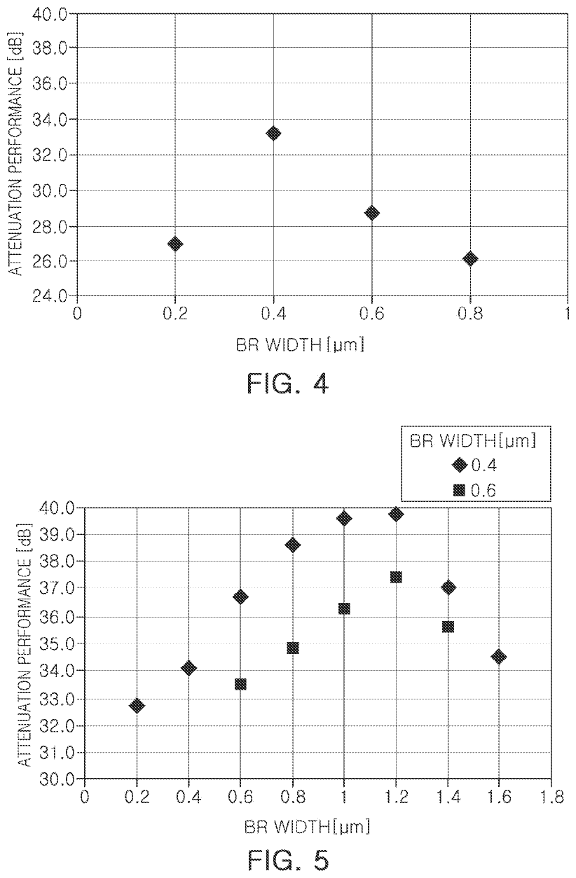

FIG. 3 is an illustrative diagram illustrating a conventional bulk-acoustic wave resonator 10. FIG. 4 is a graph illustrating attenuation performance according to a BR width in a conventional bulk-acoustic wave resonator.

Referring to FIG. 3, the resonator 10 has an area and an aspect ratio (a height/width ratio) of 4,900 μm² and 2.4, respectively. In addition, in an experiment conducted on the resonator 1, a BR width w1 illustrated in a cross section A-A′ of FIG. 3 was changed, a BE width w2 illustrated in a cross section B-B′ of FIG. 3 was kept constant at 0.4 μm. As illustrated in FIG. 4, in the experiment conducted on the resonator 10, when the BR width was 0.4 μm, it can be seen that maximum attenuation performance was 33.1 dB.

In this case, the BE width w2 refers to a width of a region in which a first electrode and an insertion layer overlap, as illustrated in FIG. 3.

The performance of the conventional resonator 10 in the experiment is illustrated in Table 1 below.

TABLE 1

| BR Width [μm] | BE Width [μm] | fs[GHz] | fp[GHz] | kt²[%] | IL[dB] | Attn.[dB] |
|---|---|---|---|---|---|---|
| 0.6 | 0.4 | 3.5620 | 3.6895 | 8.24 | 0.036 | 28.7 |
| 0.4 | | 3.5620 | 3.6905 | 8.30 | 0.036 | 33.1 |
| 0.2 | | 3.5620 | 3.6915 | 8.36 | 0.036 | 26.9 |

FIG. 5 is a graph illustrating attenuation performance according to a distance between a medial end of an insertion layer and a medial end of a lower frame, when a BR width is 0.4 μm and 0.6 μm, in the bulk-acoustic wave resonator 100 of FIGS. 1 and 2.

As illustrated in FIG. 5, it can be seen that, in an experiment conducted on the bulk-acoustic wave resonator 100, when a BR width was 0.4 μm and a distance w3 between a medial end of an insertion layer 180 and a medial end of a lower frame 210 was 1.2 μm, attenuation performance of the bulk-acoustic wave resonator 100 was 39.7 dB, demonstrating a 6.6 dB improvement, as compared to the attenuation performance of the conventional resonator 10.

As illustrated in Table 2 below, it can be seen that the following performance was exhibited, depending on the distance w3 between the medial end of the insertion layer 180 and the medial end of the lower frame 210 in the bulk-acoustic wave resonator 100.

TABLE 2

| | | Thickness of | | | | | |
|---|---|---|---|---|---|---|---|
| BR Width | Distance* | Lower Frame | Fs | Fp | kt² | IL | Attn. |
| [μm] | [μm] | [μm] | [GHz] | [GHz] | [%] | [dB] | [dB] |
| 0.4 | 0.8 | 0.1 | 3.5630 | 3.6875 | 8.06 | 0.037 | 38.7 |
| | 1.0 | | 3.5630 | 3.6868 | 8.01 | 0.037 | 39.6 |
| | 1.2 | | 3.5630 | 3.6860 | 7.97 | 0.037 | 39.7 |

*A distance between a medial end of the insertion layer and a medial end of the lower frame

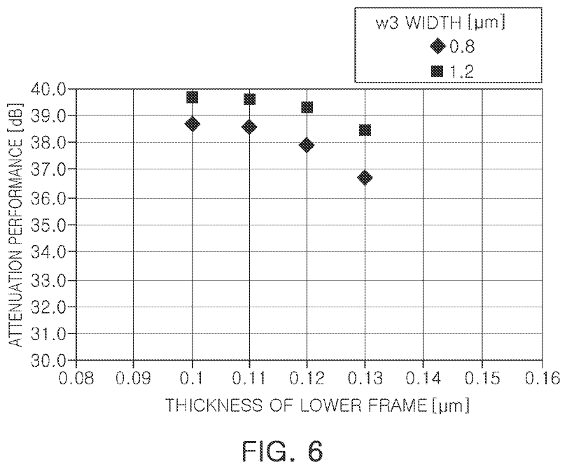

FIG. 6 is a graph illustrating attenuation performance according to a thickness of a lower frame, when a distance between a medial end of an insertion layer and a medial end of a lower frame is 0.8 μm and 1.2 μm, in the bulk-acoustic wave resonator 100 of FIGS. 1 and 2.

As illustrated in FIG. 6, it can be seen that, based on a case in which a thickness of a lower frame 210 is 0.11 μm, even when the thickness was varied by ±0.01 μm, a stable value of the attenuation performance within 1 dB was obtained.

As illustrated in Table 3 below, it may be seen that the following performance was exhibited, depending on the thickness of the lower frame 210 of the bulk-acoustic wave resonator 100.

TABLE 3

| | | Thickness of | | | | | |
|---|---|---|---|---|---|---|---|
| BR Width | Distance* | Lower Frame | Fs | Fp | kt² | IL | Attn. |
| [μm] | [μm] | [μm] | [GHz] | [GHz] | [%] | [dB] | [dB] |
| 0.4 | 1.2 | 0.10 | 3.5630 | 3.6860 | 7.97 | 0.037 | 39.7 |
| | | 0.11 | 3.5630 | 3.6855 | 7.94 | 0.037 | 39.6 |
| | | 0.12 | 3.5630 | 3.6848 | 7.89 | 0.037 | 39.4 |

*A distance between a medial end of the insertion layer and a medial end of the lower frame

As described above, performance of the bulk-acoustic wave resonator 100 was improved by the lower frame 210.

Hereinafter, a modified embodiments of bulk-acoustic wave resonators will be described. The same components as those described above may be illustrated in the drawings by the same reference numerals, and detailed descriptions thereof will not be repeated.

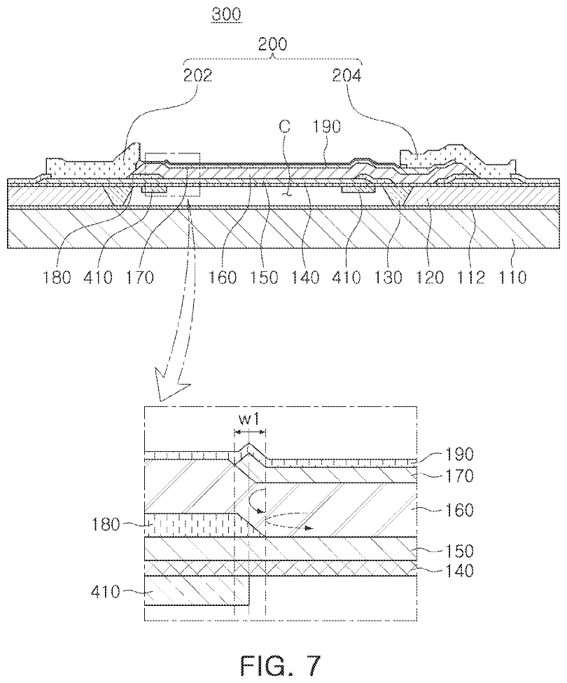

FIG. 7 is a schematic cross-sectional view illustrating a bulk-acoustic wave resonator 300, according to an embodiment.

Referring to FIG. 7, the bulk-acoustic wave resonator 300 may include, for example, the substrate 110, a sacrificial layer 120, the etch-preventing portion 130, the membrane layer 140, the first electrode 150, the piezoelectric layer 160, the second electrode 170, the insertion layer 180, the passivation layer 190, the metal pad 200, and a lower frame 410.

The substrate 110, the sacrificial layer 120, the etch-preventing portion 130, the membrane layer 140, the first electrode 150, the piezoelectric layer 160, the second electrode 170, the insertion layer 180, the passivation layer 190, and the metal pad 200 may be the same components as those described above with respect to FIGS. 1 and 2, and detailed descriptions thereof will not be repeated.

The lower frame 410 may be disposed below the membrane layer 140, and may be disposed next to the etch-preventing portion 130 in a medial direction. In addition, the lower frame 410 may have a ring shape, when viewed from above the bulk-acoustic wave resonator 300. That is, the lower frame 410 may have a ring shape in a horizontal plane parallel to the upper surface of the substrate 110.

As illustrated in FIG. 7, a medial side surface of the lower frame 410 may be disposed below the insertion layer 180. For example, the medial side surface of the lower frame 410 may be spaced apart from a medial end of the insertion layer 180 toward an outside of an active area.

In this case, a lateral wave may be first reflected by the insertion layer 180, and the lateral wave, transmitted therethrough, may be further reflected by the lower frame 410. Therefore, kt² (electromechanical coupling constant) performance of the bulk-acoustic wave resonator 300 may be improved. This may be because a width of a reflective structure on the outside the active area in the case of the bulk-acoustic wave resonator 100 may be relatively wide, and thus a parasitic capacitance component may be relatively large, whereas the bulk-acoustic wave resonator 300 maintains a width of a reflective structure to be relatively narrow, to reduce a parasitic capacitance component.

In addition, the lower frame 410 may be formed of an insulating material such as silicon oxide (SiO₂) or silicon nitride (SiN), a piezoelectric material such as pure or rare earth-doped aluminum nitride (AlN) or the like, or a material such as molybdenum (Mo), ruthenium (Ru), tungsten (W), iridium (Ir), platinum (Pt), copper (Cu), titanium (Ti), tantalum (Ta), nickel (Ni), chromium (Cr), and the like, or an alloy of molybdenum (Mo), ruthenium (Ru), tungsten (W), iridium (Ir), platinum (Pt), copper (Cu), titanium (Ti), tantalum (Ta), nickel (Ni), or chromium (Cr).

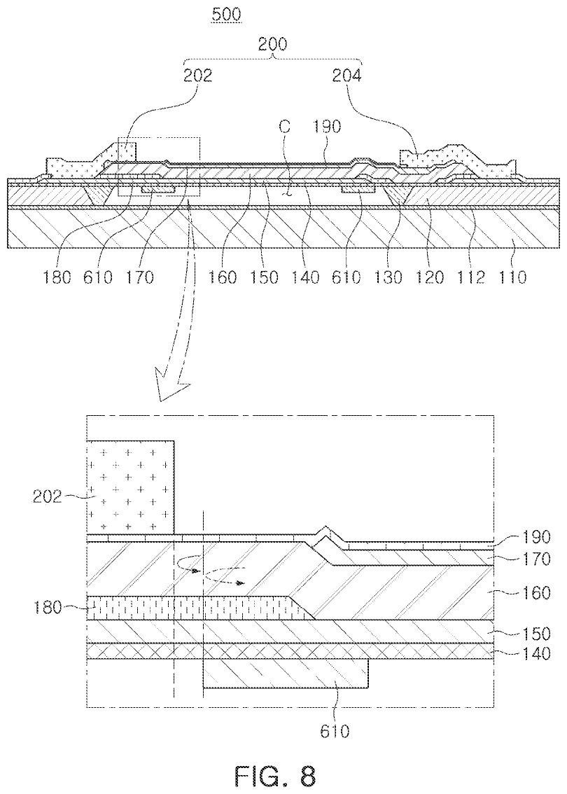

FIG. 8 is a schematic cross-sectional view illustrating a bulk-acoustic wave resonator 500, according to an embodiment.

Referring to FIG. 8, the bulk-acoustic wave resonator 500 may include, for example, the substrate 110, the sacrificial layer 120, the etch-preventing portion 130, the membrane layer 140, the first electrode 150, the piezoelectric layer 160, the second electrode 170, an insertion layer 180, the passivation layer 190, the metal pad 200, and a lower frame 610.

The substrate 110, the sacrificial layer 120, the etch-preventing portion 130, the membrane layer 140, the first electrode 150, the piezoelectric layer 160, the second electrode 170, the insertion layer 180, the passivation layer 190, and the metal pad 200 may be the same components as those described above, and detailed descriptions thereof will not be repeated.

The lower frame 610 may be disposed below the membrane layer 140, and may be disposed next to the etch-preventing portion 130 in a medial direction. In addition, the lower frame 610 may have a ring shape, when viewed from above the bulk-acoustic wave resonator 500. That is, the lower frame 610 may have a ring shape in a horizontal plane parallel to the upper surface of the substrate 110.

As illustrated in FIG. 8, a medial side surface of the lower frame 610 may be disposed to protrude from a medial end of the insertion layer 180 toward an active area (e.g., toward a central portion of the bulk-acoustic wave resonator 500). The lateral side surface of the lower frame 610 may be spaced apart from a medial end of the metal pad 200 toward the active area (e.g., toward the central portion of the bulk-acoustic wave resonator 500).

In this case, a lateral wave leaking out of the active area may be reflected from a lateral side surface of the lower frame 610, and the lateral wave transmitted through the lateral side surface of the lower frame 610 may be additionally reflected by the metal pad 200.

In addition, the lower frame 610 may be formed of an insulating material such as silicon oxide (SiO₂) or silicon nitride (SiN), a piezoelectric material such as pure or rare earth-doped aluminum nitride (AlN) or the like, or a material such as molybdenum (Mo), ruthenium (Ru), tungsten (W), iridium (Ir), platinum (Pt), copper (Cu), titanium (Ti), tantalum (Ta), nickel (Ni), chromium (Cr), and the like, or an alloy of molybdenum (Mo), ruthenium (Ru), tungsten (W), iridium (Ir), platinum (Pt), copper (Cu), titanium (Ti), tantalum (Ta), nickel (Ni), or chromium (Cr).

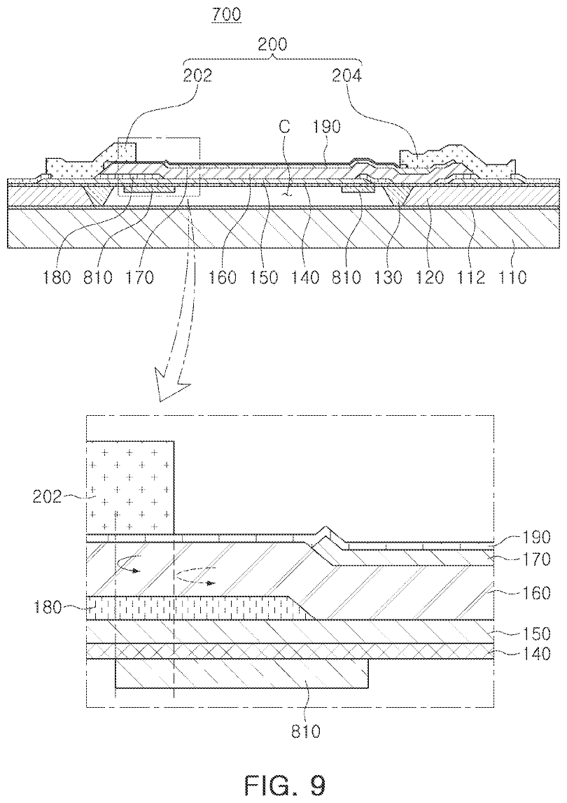

FIG. 9 is a schematic cross-sectional view illustrating a bulk-acoustic wave resonator 700, according to an embodiment.

Referring to FIG. 9, the bulk-acoustic wave resonator 700 may include, for example, the substrate 110, the sacrificial layer 120, the etch-preventing portion 130, the membrane layer 140, the first electrode 150, the piezoelectric layer 160, the second electrode 170, the insertion layer 180, the passivation layer 190, the metal pad 200, and a lower frame 810.

The substrate 110, the sacrificial layer 120, the etch-preventing portion 130, the membrane layer 140, the first electrode 150, the piezoelectric layer 160, the second electrode 170, the insertion layer 180, the passivation layer 190, and the metal pad 200 may be the same components as those described above, and detailed descriptions thereof will not be repeated.

The lower frame 810 may be disposed below the membrane layer 140, and may be disposed next to the etch-preventing portion 130 in a medial direction. In addition, the lower frame 810 may have a ring shape, when viewed from above the bulk-acoustic wave resonator 700. That is, the lower frame 810 may have a ring shape in a horizontal plane parallel to the upper surface of the substrate 110. As illustrated in FIG. 9, a medial side surface of the lower frame 810 may be disposed to protrude from a medial end of the insertion layer 180 toward an active area (e.g., toward a central portion of the bulk-acoustic wave resonator 700). A lateral side surface of the lower frame 810 may be spaced apart from a medial end of the metal pad 200 toward an outside of the active area (e.g., toward an edge portion of the bulk-acoustic wave resonator 700).

In this case, a lateral wave leaking out of the active area may be reflected by the metal pad 200, and the lateral wave transmitted through the medial surface of the metal pad 200 may be additionally reflected by the medial side surface of the lower frame 810.

In addition, the lower frame 810 may be formed of an insulating material such as silicon oxide (SiO₂) or silicon nitride (SiN), a piezoelectric material such as pure or rare earth-doped aluminum nitride (AlN) or the like, or a material such as molybdenum (Mo), ruthenium (Ru), tungsten (W), iridium (Ir), platinum (Pt), copper (Cu), titanium (Ti), tantalum (Ta), nickel (Ni), chromium (Cr), and the like, or an alloy of molybdenum (Mo), ruthenium (Ru), tungsten (W), iridium (Ir), platinum (Pt), copper (Cu), titanium (Ti), tantalum (Ta), nickel (Ni), or chromium (Cr).

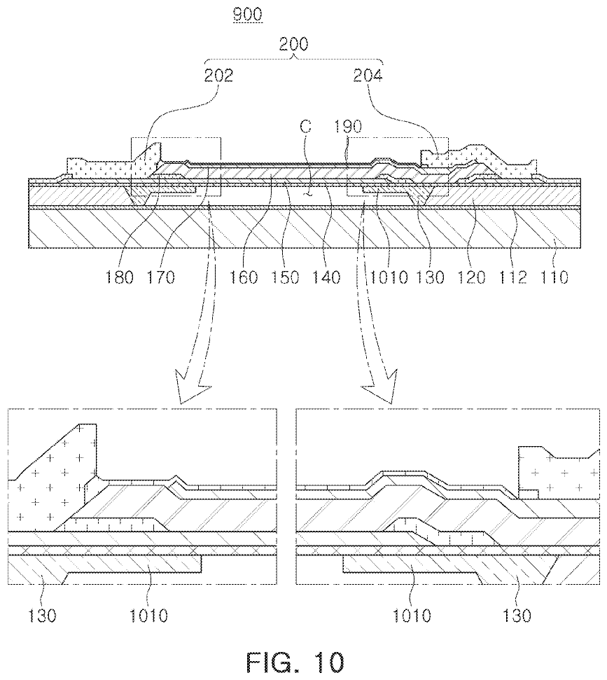

FIG. 10 is a schematic cross-sectional view illustrating a bulk-acoustic wave resonator 900, according to an embodiment.

Referring to FIG. 10, the bulk-acoustic wave resonator 900 may include, for example, the substrate 110, the sacrificial layer 120, an etch-preventing portion 130, the membrane layer 140, the first electrode 150, the piezoelectric layer 160, the second electrode 170, the insertion layer 180, the passivation layer 190, the metal pad 200, and a lower frame 1010.

The substrate 110, the sacrificial layer 120, the etch-preventing portion 130, the membrane layer 140, the first electrode 150, the piezoelectric layer 160, the second electrode 170, the insertion layer 180, the passivation layer 190, and the metal pad 200 may be the same components as those described above, and detailed descriptions thereof will not be repeated.

The lower frame 1010 may be disposed below the membrane layer 140, and may be disposed next to the etch-preventing portion 130 in a medial direction. For example, the lower frame 1010 may be formed integrally with the etch-preventing portion 130 or may be connected to the etch-preventing portion 130. For example, the lower frame 1010 may be formed by a portion of the etch-preventing portion 130 that is elongated in the medial direction and has a reduced thickness in comparison to a remainder of the etch-preventing portion 130. In addition, the lower frame 1010 may have a ring shape, when viewed from above the bulk-acoustic wave resonator 900. That is, the lower frame 1010 may have a ring shape in a horizontal plane parallel to the upper surface of the substrate 110.

As illustrated in FIG. 10, a medial side surface of the lower frame 1010 may be disposed to protrude from a medial end of the insertion layer 180 toward an active area (e.g., toward a central portion of the bulk-acoustic wave resonator 900).

In addition, the lower frame 1010 may be formed of an insulating material such as silicon oxide (SiO₂) or silicon nitride (SiN), a piezoelectric material such as pure or rare earth-doped aluminum nitride (AlN) or the like, or a material such as molybdenum (Mo), ruthenium (Ru), tungsten (W), iridium (Ir), platinum (Pt), copper (Cu), titanium (Ti), tantalum (Ta), nickel (Ni), chromium (Cr), and the like, or an alloy of molybdenum (Mo), ruthenium (Ru), tungsten (W), iridium (Ir), platinum (Pt), copper (Cu), titanium (Ti), tantalum (Ta), nickel (Ni), or chromium (Cr).

According to embodiments disclosed herein, a bulk-acoustic wave resonator may have improved attenuation performance.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk-acoustic wave resonator, comprising:
a substrate;
a first electrode disposed on the substrate;
a cavity disposed between the substrate and the first electrode;
a piezoelectric layer covering at least a portion of the first electrode;
a second electrode covering at least a portion of the piezoelectric layer;
an insertion layer disposed between the first electrode and the piezoelectric layer; and
a lower frame disposed in the cavity,
wherein at least a portion of the lower frame overlaps the insertion layer.

2. The bulk-acoustic wave resonator of claim 1, wherein a medial side surface of the lower frame protrudes from a medial end of the insertion layer toward an active area in which the first electrode, the piezoelectric layer, and the second electrode overlap.

3. The bulk-acoustic wave resonator of claim 1, wherein a width of a region in which a medial end portion of the insertion layer and an end portion of the second electrode overlap is 0.2 μm to 0.8 μm.

4. The bulk-acoustic wave resonator of claim 1, wherein a distance between a medial end of the insertion layer and a medial end of the lower frame, in a medial direction of the bulk-acoustic wave resonator, is 0.4 μm to 1.2 μm.

5. The bulk-acoustic wave resonator of claim 1, wherein a thickness of the lower frame is 0.08 μm to 0.15 μm.

6. The bulk-acoustic wave resonator of claim 1, wherein a medial side surface of the lower frame is spaced apart from a medial end of the insertion layer toward an outside of an active area in which the first electrode, the piezoelectric layer, and the second electrode overlap.

7. The bulk-acoustic wave resonator of claim 1, further comprising a membrane layer forming the cavity together with the substrate.

8. The bulk-acoustic wave resonator of claim 1, further comprising:
an etch-preventing portion disposed to surround the cavity;
a sacrificial layer disposed to surround the etch-preventing portion; and
a metal pad connected to the first electrode and the second electrode.

9. The bulk-acoustic wave resonator of claim 8, wherein a lateral side surface of the lower frame is spaced apart from a medial side surface of the metal pad toward an active area in which the first electrode, the piezoelectric layer, and the second electrode overlap.

10. The bulk-acoustic wave resonator of claim 9, wherein a width of a region in which a medial end portion of the insertion layer and an end portion of the second electrode overlap is 0.2 μm to 0.8 μm.

11. The bulk-acoustic wave resonator of claim 9, wherein a thickness of the lower frame is 0.08 μm to 0.15 μm.

12. The bulk-acoustic wave resonator of claim 8, wherein a lateral side surface of the lower frame is spaced apart from a medial side surface of the metal pad toward an outside of an active area in which the first electrode, the piezoelectric layer, and the second electrode overlap.

13. The bulk-acoustic wave resonator of claim 8, wherein the lower frame is connected to the etch-preventing portion.

14. The bulk-acoustic wave resonator of claim 8, wherein the lower frame is a portion of the etch-preventing portion.

15. The bulk-acoustic wave resonator of claim 8, wherein the lower frame extends from a remaining portion of the etch-preventing portion toward a center of an active area in which the first electrode, the piezoelectric layer, and the second electrode overlap, and
wherein a thickness of the lower frame is less than a thickness of the remaining portion of the etch-preventing portion.

16. A bulk-acoustic wave resonator, comprising:
a substrate;
a cavity disposed on the substrate;
a lower electrode disposed on an upper portion of the cavity;
a piezoelectric layer disposed on the lower electrode;
an upper electrode disposed on the piezoelectric layer such that the piezoelectric layer is disposed between the first electrode and the second electrode;
an insertion layer disposed between portions of the lower electrode and the piezoelectric layer; and
a lower frame disposed in the cavity, on a lower surface of lower electrode, such that the lower frame at least partially overlaps the insertion layer.

17. The bulk-acoustic wave resonator of claim 16, wherein the lower frame extends farther than the insertion layer in a horizontal direction toward a center of the bulk-acoustic wave resonator.

18. The bulk-acoustic wave resonator of claim 17, wherein the insertion layer extends farther than the lower frame in a horizontal direction away from the center of the bulk-acoustic wave resonator.

19. The bulk-acoustic wave resonator of claim 16, wherein the lower frame extends farther than the insertion layer in a horizontal direction away from a center of the bulk-acoustic wave resonator.
